(19) United States
(12) Patent Application Publication
(10) Pub. No.: US 2014/0216804 A1
(43) Pub. Date: Aug. 7, 2014

(54) Transparent Conductive Film

(71) Applicant: NANCHANG O-FILM TECH. CO., LTD., Nanchang (CN)

(72) Inventors: Guangzhou Yang, Nanchang (CN); Miaoqian Cao, Nanchang (CN); Yulong Gao, Nanchang (CN); Chao Sun, Nanchang (CN)

(73) Assignee: NANCHANG O-FILM TECH. CO., LTD., Nanchang (CN)

(21) Appl. No.: 14/001,650

(22) PCT Filed: Jul. 5, 2013
(86) PCT No.: PCT/CN13/78938

§ 371 Date: Aug. 26, 2013

(30) Foreign Application Priority Data
Feb. 4, 2013 (CN) 201310044167.3

(51) Int. Cl. H05K 1/02

(52) U.S. Cl. CPC H05K 1/0296
USPC 174/268

(57) ABSTRACT

A transparent conductive film includes a substrate defining a mesh-shaped groove, which forms a mesh; and a conductive layer formed by conductive material filled in the mesh. An edge line of the mesh-shaped grooves is a curve or a polyline which increases a contact area between the conductive material and an edge of the mesh-shaped groove. In the transparent conductive film, non-linear edge lines are used, therefore, for the conductive region with the same size, the area of edge of the conductive material in contact with the trench increases, and the friction is increased, which leads to a larger adhesion of the conductive material, and a stable performance of the transparent conductive film is guaranteed.

### FIELD OF THE INVENTION

The present invention relates to conductive films, and more particularly relates to a transparent conductive film.

### BACKGROUND OF THE INVENTION

The transparent conductive film is a conductive film which exhibits excellent properties of high conductivity and good transmittance for visible light, thus it has a broad application prospects. Currently, the transparent conductive film has been successfully used in fields of liquid crystal displays, touch panels, electromagnetic shielding, transparent surface heater of transparent electrode of the solar cell, and flexible light-emitting devices.

The conventional transparent conductive film usually needs to be patterned through exposure, development, etching, cleaning, and other procedures, such that a conductive region and a transmission region are formed on the surface of the substrate according to the pattern. Or the metal mesh can be formed on a specific region on the substrate by printing. The grid line is made of metal having a good conductivity and not transparent, and the linewidth of the grid line is less than the resolution of the human eye. The transmission region is the mesh formed by grid lines, the square resistance and the transmittance of the transparent conductive film is controlled by adjusting the shape of the mesh. In performance tests for the conductive film, adhesion of the conductive film can affect properties of the conductive film, therefore the adhesion of the metal mesh on the substrate is an important parameter in the performance tests. Metal grid lines are generally straight, which results in the adhesion of the metal mesh is not stable enough, and a poor adhesion of the conductive film will seriously affect the performances of the conductive film.

### SUMMARY OF THE INVENTION

It is an object of the present invention to provide a transparent conductive film with a better adhesion of a conductive layer.

A transparent conductive film includes: a substrate defining a mesh-shaped groove, the mesh-shaped groove forming a mesh; and a conductive layer formed by conductive material filled in the mesh; wherein an edge line of the mesh-shaped groove is a curve or a polyline which is configured to increase a contact area between the conductive material and an edge of the mesh-shaped groove.

In one embodiment, the polyline is a rectangular wave line.

In one embodiment, the polyline is a zigzag line.

In one embodiment, the polyline is a wave line.

In one embodiment, a cell of the mesh is selected from the group consisting of hexagonal, rectangular, diamond, and irregular polygon.

In one embodiment, the curve or the polyline oscillates with a constant amplitude along a straight line edge of the hexagonal, rectangular, diamond or irregular polygon.

In one embodiment, the mesh is evenly distributed on a surface of the conductive layer.

In one embodiment, a grid line between two nodes of the mesh forms an angle θ with a horizontal X axis, the angle θ is evenly-distributed, the uniform distribution refers to the statistic value θ of each of the random grids; then gathering statistics for a probability pᵢ of the grid lines falling within each of angle intervals at a stepper angle 5°, thus obtaining p₁, p₂. . . p₃₆ in the 36 angle intervals within 0˜180°; pᵢ satisfies that the standard deviation is less than 20% of an arithmetic mean.

A transparent conductive film includes: a substrate; an imprint adhesive layer attached to the substrate, the imprint adhesive layer defining a mesh-shaped groove, the mesh-shaped groove forming a mesh; and a conductive layer formed by conductive material filled in the mesh; wherein an edge line of the mesh-shaped groove is a curve or a polyline which is configured to increase a contact area between the conductive material and an edge of the mesh-shaped groove.

In one embodiment, the polyline is a rectangular wave line.

In one embodiment, the polyline is a zigzag line.

In one embodiment, the polyline is a wave line.

In one embodiment, a cell of the mesh is selected from the group consisting of hexagonal, rectangular, diamond, and irregular polygon.

In one embodiment, the curve or the polyline oscillates with a constant amplitude along a straight line edge of the hexagonal, rectangular, diamond or irregular polygon.

In one embodiment, the mesh is evenly distributed on a surface of the conductive layer.

In one embodiment, a grid line between two nodes of the mesh forms an angle θ with a horizontal X axis, the angle θ is evenly-distributed, the uniform distribution refers to the statistic value θ of each of the random grids; then gathering statistics for a probability pᵢ of the grid lines falling within each of angle intervals at a stepper angle 5°, thus obtaining p₁, p₂ . . . p₃₆ in the 36 angle intervals within 0˜180°; pᵢ satisfies that the standard deviation is less than 20% of an arithmetic mean.

In one embodiment, the transparent conductive film further includes a tackifier layer disposed between the substrate and the imprint adhesive layer.

In the described transparent conductive film, the conductive layer includes the conductive material filled in the mesh-shaped groove, and the edge line of the mesh-shaped groove is a curve or a polyline, such as wave line, zigzag line, rectangular wave line, or other non-linear lines. For the conductive region with the same size, the area of edge of the conductive material in contact with the trench increases, and the friction is increased, which leads to a larger adhesion of the conductive material, and a stable performance of the transparent conductive film is guaranteed.

### BRIEF DESCRIPTION OF THE DRAWINGS

FIG. 1A is a schematic, cross-section view of an embodiment of a transparent conductive film;

FIG. 1B is a schematic, cross-section view of another embodiment of a transparent conductive film;

FIG. 2A is a partial, enlarged view of a mesh of the transparent conductive film of Comparative Example 1;

FIG. 2B is a partial, enlarged view of a mesh of the transparent conductive film of Example 1;

FIG. 2C is a partial, enlarged view of a mesh cell of the transparent conductive film of Example 1;

FIG. 3A is a partial, enlarged view of a mesh cell of the transparent conductive film of Comparative Example 2;

FIG. 3B is a partial, enlarged view of a mesh of the transparent conductive film of Example 2;

FIG. 3C is a partial, enlarged view of a mesh cell of the transparent conductive film of Example 2;

FIG. 4A is a partial, enlarged view of a mesh cell of the transparent conductive film of Comparative Example 3;

FIG. 4B is a partial, enlarged view of a mesh of the transparent conductive film of Example 3;

FIG. 4C is a partial, enlarged view of a mesh cell of the transparent conductive film of Example 3.

### DETAILED DESCRIPTION

The invention will be described in further detail below in conjunction with the drawing.

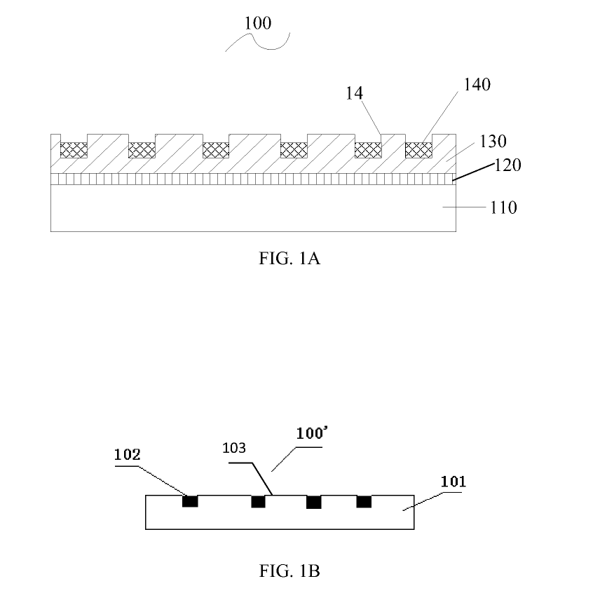

Referring to FIG. 1A, a first embodiment of a transparent conductive film 100, from bottom to up, includes a substrate 110, a tackifier layer 120, an imprint adhesive layer 130, and a conductive layer 140.

The substrate 110 has a thickness of 188 μm. The substrate 110 can be made of polyethylene terephthalate (PET). In alternative embodiments, it can be made of other transparent plastic.

The tackifier layer 120 is bonded to the substrate 110 and is configured to better bond the substrate layer 110 and the imprint adhesive layer 130 together. In alternative embodiments, the tackifier layer 120 can be omitted, such that the imprint adhesive layer 130 is disposed on the substrate 110 directly.

The imprint adhesive layer 130 is bonded to the tackifier layer 120. The imprint adhesive layer 130 is made of acrylic material, UV glue or imprint glue, etc. The imprint adhesive layer 130 defines a mesh-shaped groove 14 by imprinting. The mesh-shaped groove 14 has a depth of 3 μm, a width of 2.2 μm. The mesh-shaped groove forms a mesh. An edge line of the mesh-shaped groove 14 can be a curve or a polyline, such as wave line, zigzag line, rectangular wave line, or other non-linear lines. Each cell forming the mesh has a shape selected from the group consisting of hexagonal, rectangular, diamond, and irregular polygon. The curve or the polyline oscillates with a constant amplitude along a straight line edge of the hexagonal, rectangular, diamond or irregular polygon. In alternative embodiments, the curve or the polyline can oscillates back and forth along a straight line edge of the hexagonal, rectangular, diamond or irregular polygon. In one embodiment, the mesh is evenly distributed on a surface of the conductive layer 140, which satisfies the condition: a grid line between two nodes of the mesh forms an angle θ with a horizontal X axis, the angle θ is evenly-distributed, the uniform distribution refers to the statistic value θ of each of the random grids; then gathering statistics for a probability pᵢ of the grid lines falling within each of angle intervals at a stepper angle 5°, thus obtaining p₁, p₂ . . . p₃₆ in the 36 angle intervals within 0˜180°; pᵢ satisfies that the standard deviation is less than 20% of an arithmetic mean.

The conductive layer 140 is formed by a conductive material filled in the mesh-shaped groove 14. In the illustrated embodiment, the conductive material is silver. The thickness of the conductive material is less than the depth of the mesh-shaped groove 14. For example, if the depth of the mesh-shaped groove 14 is 3 μm, the thickness of the conductive material is about 2 μm.

Referring to FIG. 1B, another embodiment of a transparent conductive film 100′ is similar to the transparent conductive film 100 shown in FIG. 1A, the distinction is that, the transparent conductive film 100′ includes a substrate 101 and a conductive layer 102. The substrate 101 is made of thermoplastic materials, such as polymethylmethacrylate (PMMA), Polycarbonate (PC), and the like. The substrate 101 defines a mesh-shaped groove 103 on a surface; a conductive material (e.g. silver) is filled in the mesh-shaped groove 103 to form the conductive layer 102. The shape of the mesh-shaped groove 103 is the same as that of the mesh-shaped groove 14 shown in FIG. 1A.

In the described transparent conductive film, the conductive layer includes the conductive material filled in the mesh-shaped groove, and the interconnected conductive material forms a conductive region. The mesh-shaped groove forms the mesh. The edge line of the mesh-shaped groove is a curve or a polyline, such as wave line, zigzag line, rectangular wave line, or other non-linear lines. The cell forming the mesh has a shape selected from the group consisting of hexagonal, rectangular, diamond, and irregular polygon. The curve or the polyline oscillates with a constant amplitude along a straight line edge of the hexagonal, rectangular, diamond or irregular polygon. For the conductive region with the same size, the area of edge of the conductive material in contact with the trench increases, and the friction is increased, which leads to a larger adhesion of the conductive material, and a stable performance of the transparent conductive film is guaranteed.

The following specific embodiments of the surface structure of the conductive layer 140 will be described in details.

### Comparative Example 1

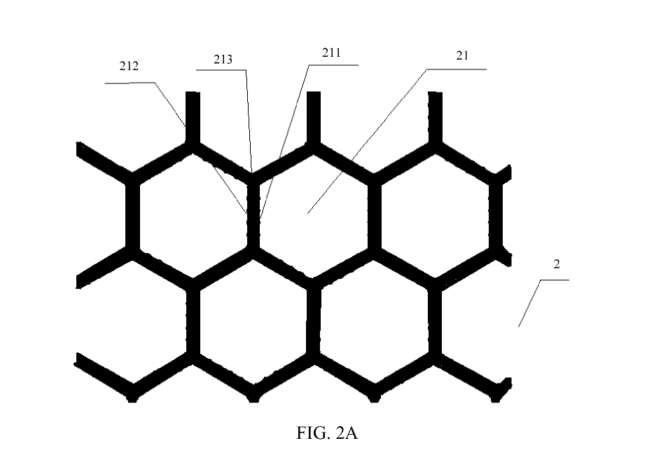

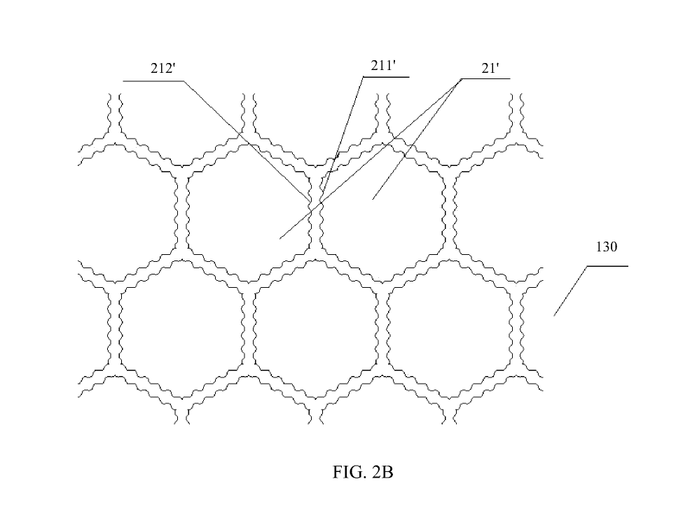

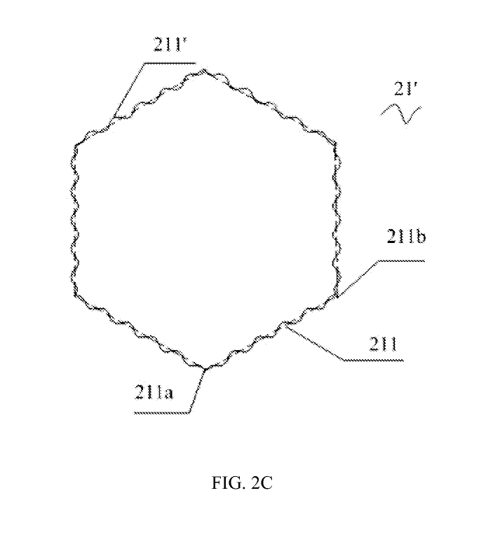

FIG. 2A is a partial, enlarged view of a mesh of a conventional transparent conductive film 2, which includes a plurality of mesh cell 21 horizontally arranged in an array. The mesh cell 21 is shaped as a hexagonal, and edge line 211 and edge line 212 belong to two adjacent mesh cells 21, the edge line 211 and the edge line 212 are both straight lines. A trench is formed between the edge line 211 and the edge line 212, a spacing of the trench ranges from 400 nm to 5 μm. A conductive material 213 is filled in the trench, and the edge line 211 and the edge line 212 form a conductive trace.

### Example 1

FIG. 2B is a partial, enlarged view of a mesh of the conductive layer 140 of the transparent conductive film 100. The conductive layer 140 includes a mesh formed by the mesh-shaped groove 14, and the mesh includes a plurality of mesh cell 21′ horizontally arranged in an array. An edge line 211′ and edge line 212′ of the mesh-shaped groove 14 belong to two adjacent mesh cells 21′. The edge line 211′ and the edge line 212′ are wave lines. The mesh cell 21′ is shaped as a waved-hexagonal. A trench is formed between the edge line 211′ and the edge line 212′, a spacing of the trench ranges from 400 nm to 5 μm. A conductive material is filled in the trench, and the edge line 211′ and the edge line 212′ form a conductive trace.

FIG. 2C is a partial, enlarged view of a mesh cell 21′ of the transparent conductive film 100 of Example 1. The mesh cell 21′ is shaped as a substantially hexagonal. The grid line of the mesh cell 21′ is composed of the edge line 211′. The edge line 211′ is a wave line, the line 221 is a dashed line. The line 221 extends from a vertex 211a to a vertex 211b, and a hexagonal is formed in accordance with this rule. The edge line 211′ surrounds the grid line 211 and extends from a vertex 211a to a vertex 211b, and a waved-hexagonal mesh cell 21′ is formed in accordance with this rule. The edge line 211′ oscillates around line 221 with a constant amplitude.

### Comparative Example 2

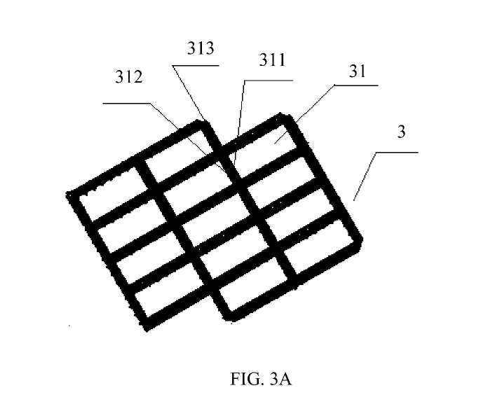

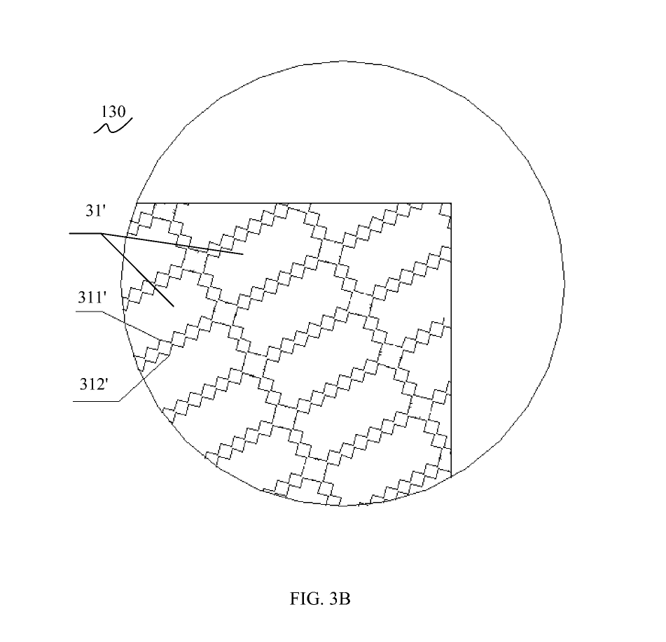

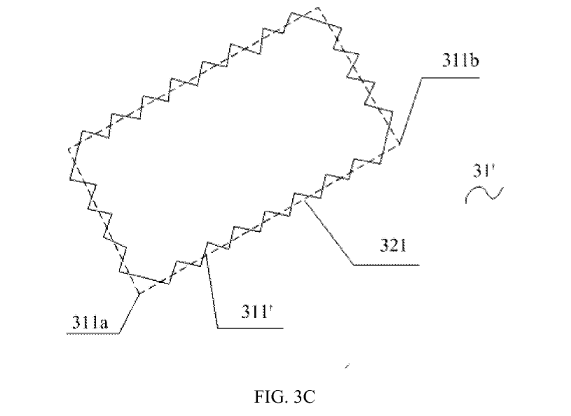

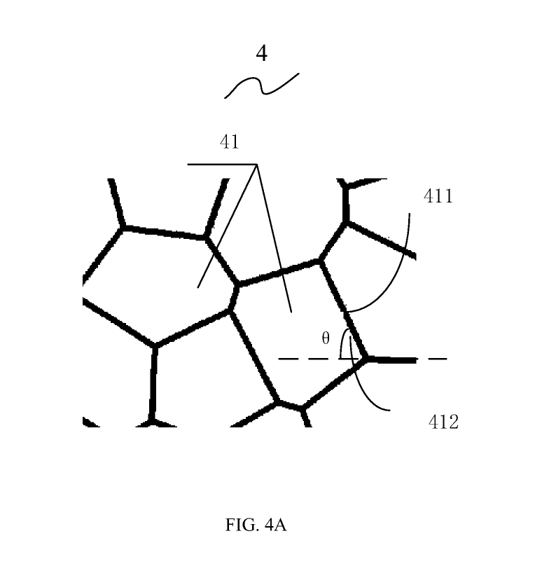

FIG. 3A is a partial, enlarged view of a mesh of a conductive layer of a conventional transparent conductive film 3, a surface of the conductive layer of the transparent conductive film 3 includes a plurality of mesh cells 31. The mesh cell 31 is shaped as a rectangular inclined at a predetermined angle, such that the distribution probability of the grid lines near the horizontal axis is greater than that near the longitudinal axis. The plurality of horizontal mesh cells 31 arranged in an array form the transparent conductive film 3. Edge line 311 and edge line 312 belong to two adjacent mesh cells 31. A trench is formed between the edge line 311 and the edge line 312. A conductive material 313 is filled in the trench, the edge line 311 and the edge line 312 are both straight lines, and the edge line 311 and the edge line 312 form a trace.

### Example 2

FIG. 3B is a partial, enlarged view of a mesh of the conductive layer 140 of the transparent conductive film 100. The conductive layer 140 includes a mesh formed by the mesh-shaped groove 14, and the mesh includes a plurality of mesh cell 31′ horizontally arranged in an array. The mesh cell 31′ is shaped as a rectangular inclined at a predetermined angle, such that the distribution probability of the grid lines near the horizontal axis is greater than that near the longitudinal axis. The edge line 311′ and edge line 312′ of the mesh-shaped groove 14 belong to two adjacent mesh cells 31′. The edge line 311′ and edge line 312′ are zigzag lines. A conductive material is filled in the trench formed by the edge line 311′ and edge line 312′, and the edge line 311′ and the edge line 312′ form a trace.

FIG. 3C is a partial, enlarged view of a mesh cell 31′ of the transparent conductive film 100 of Example 2. The grid line of the mesh cell 31′ is composed of edge lines 311′. The line 321 is a dashed line. The line 321 extends from a vertex 311a to a vertex 311b, and a rectangular is formed in accordance with this rule. The edge line 311′ surrounds the grid line 321 and extends from a vertex 311a to a vertex 311b, thus the mesh cell 31′ is formed. The edge line 311′ oscillates around line 321 with a constant amplitude.

### Comparative Example 3

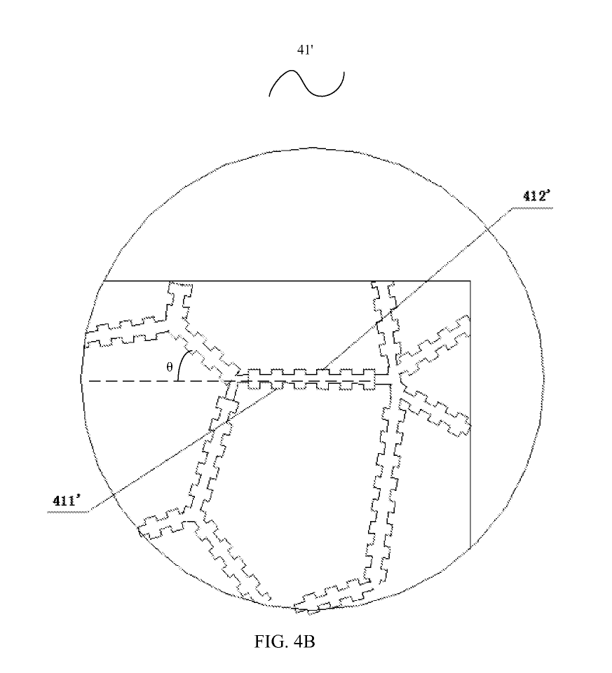

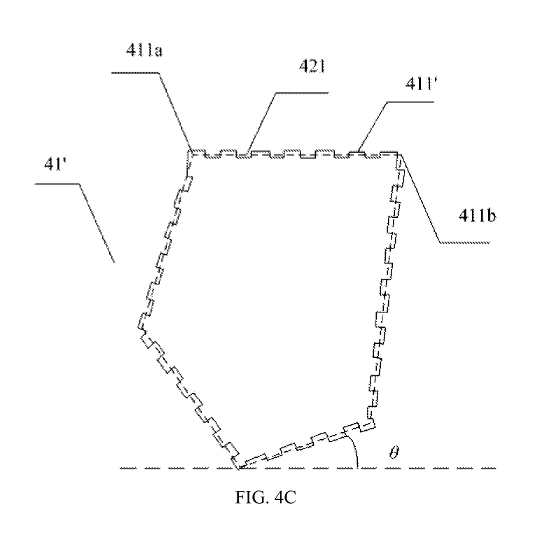

FIG. 4A is a partial, enlarged view of a mesh of a conductive layer of a conventional transparent conductive film 4. The mesh of the conductive layer 140 includes a plurality of mesh cells 41, a trench is formed between two adjacent edge lines 411 and the edge line 412 of the mesh cell 41, and a conductive material is filled in the trench. The edge line 411 and the edge line 412 are both straight lines. An angle formed by the grid line and right horizontal X axis is evenly distributed. A grid line as shown in FIG. 4A forms an angle θ with right horizontal X axis, the uniform distribution refers to the statistic value θ of each of the random grids; then gathering statistics for a probability pᵢ of the grid lines falling within each of angle intervals at a stepper angle 5°, thus obtaining p₁, p₂ . . . p₃₆ in the 36 angle intervals within 0˜180°; pᵢ satisfies that the standard deviation is less than 20% of an arithmetic mean.

### Example 3

FIG. 4B is a partial, enlarged view of a mesh of the conductive layer 140 of the transparent conductive film 100 according to Example 3. The conductive layer 140 includes a mesh formed by the mesh-shaped groove 14, and the mesh includes a plurality of mesh cell 41′ horizontally arranged in an array. The grid line of the mesh cell 41′ is composed of a line 411′ and edge line 412′ of the mesh-shaped groove 14. The edge line 411′ and edge line 412′ are rectangular wave lines. A grid line as shown in FIG. 4B forms an angle θ with right horizontal X axis, the uniform distribution refers to the statistic value θ of each of the random grids; then gathering statistics for a probability pᵢ of the grid lines falling within each of angle intervals at a stepper angle 5°, thus obtaining p₁,p₂ . . . p₃₆ in the 36 angle intervals within 0˜180°; pᵢ satisfies that the standard deviation is less than 20% of an arithmetic mean.

FIG. 4C is a partial, enlarged view of a mesh cell 41′ of the transparent conductive film 100 of Example 3. The grid line of the mesh cell 41′ is composed of edge lines 411′. The line 421 is a dashed line. The edge line 411′ is a rectangular wave line. A grid line of the meshed cell 41′ forms an angle θ with right horizontal X axis, the uniform distribution refers to the statistic value θ of each of the random grids; then gathering statistics for a probability pᵢ of the grid lines falling within each of angle intervals at a stepper angle 5°, thus obtaining p₁, p₂ . . . p₃₆ in the 36 angle intervals within 0˜180°; pᵢ satisfies that the standard deviation is less than 20% of an arithmetic mean. The line 421 extends from a vertex 411a to a vertex 411b, and a random shape is formed in accordance with this rule. The edge line 411′ surrounds the grid line 421 and extends from a vertex 411a to a vertex 411b, thus the mesh cell 41′ is formed. The edge line 411′ oscillates around line 421 with a constant amplitude.

According to the described Examples, for the conductive region with the same size, the area of edge of the conductive material in contact with the trench increases, and the friction is increased, which leads to a larger adhesion of the conductive material, and a stable performance of the transparent conductive film is guaranteed.

Although the invention has been described in language specific to structural features and/or methodological acts, it is to be understood that the invention defined in the appended claims is not necessarily limited to the specific features or acts described. Rather, the specific features and acts are disclosed as sample forms of implementing the claimed invention.

What is claimed is:

1. A transparent conductive film, comprising:
a substrate defining a mesh-shaped groove, the mesh-shaped groove forming a mesh; and
a conductive layer formed by conductive material filled in the mesh;
wherein an edge line of the mesh-shaped groove is a curve or a polyline which is configured to increase a contact area between the conductive material and an edge of the mesh-shaped groove.

2. The transparent conductive film according to claim 1, wherein the polyline is a rectangular wave line.

3. The transparent conductive film according to claim 1, wherein the polyline is a zigzag line.

4. The transparent conductive film according to claim 1, wherein the polyline is a wave line.

5. The transparent conductive film according to claim 1, wherein a cell of the mesh is selected from the group consisting of hexagonal, rectangular, diamond, and irregular polygon.

6. The transparent conductive film according to claim 5, wherein the curve or the polyline oscillates with a constant amplitude along a straight line edge of the hexagonal, rectangular, diamond or irregular polygon.

7. The transparent conductive film according to claim 1, wherein the mesh is evenly distributed on a surface of the conductive layer.

8. The transparent conductive film according to claim 1, wherein a grid line between two nodes of the mesh forms an angle θ with a horizontal X axis, the angle θ is evenly-distributed, the uniform distribution refers to the statistic value θ of each of the random grids; then gathering statistics for a probability pᵢ of the grid lines falling within each of angle intervals at a stepper angle 5°, thus obtaining p₁, p₂ . . . p₃₆ in the 36 angle intervals within 0˜180°; pᵢ satisfies that the standard deviation is less than 20% of an arithmetic mean.

9. A transparent conductive film, comprising:
a substrate;
an imprint adhesive layer attached to the substrate, the imprint adhesive layer defining a mesh-shaped groove, the mesh-shaped groove forming a mesh; and
a conductive layer formed by conductive material filled in the mesh;
wherein an edge line of the mesh-shaped groove is a curve or a polyline which is configured to increase a contact area between the conductive material and an edge of the mesh-shaped groove.

10. The transparent conductive film according to claim 9, wherein the polyline is a rectangular wave line.

11. The transparent conductive film according to claim 9, wherein the polyline is a zigzag line.

12. The transparent conductive film according to claim 9, wherein the polyline is a wave line.

13. The transparent conductive film according to claim 9, wherein a cell of the mesh is selected from the group consisting of hexagonal, rectangular, diamond, and irregular polygon.

14. The transparent conductive film according to claim 13, wherein the curve or the polyline oscillates with constant amplitude along a straight line edge of the hexagonal, rectangular, diamond or irregular polygon.

15. The transparent conductive film according to claim 9, wherein the mesh is evenly distributed on a surface of the conductive layer.

16. The transparent conductive film according to claim 9, wherein a grid line between two nodes of the mesh forms an angle θ with a horizontal X axis, the angle θ is evenly-distributed, the uniform distribution refers to the statistic value θ of each of the random grids; then gathering statistics for a probability pᵢ of the grid lines falling within each of angle intervals at a stepper angle 5°, thus obtaining p₁, p₂. . . p₃₆ in the 36 angle intervals within 0˜180°; pᵢ satisfies that the standard deviation is less than 20% of an arithmetic mean.

17. The transparent conductive film according to claim 1, further comprising a tackifier layer disposed between the substrate and the imprint adhesive layer.
